(19) United States
(12) Patent Application Publication
(10) Pub. No.: US 2008/0020499 A1
(43) Pub. Date: Jan. 24, 2008

(54) Nanotube assembly including protective layer and method for making the same

(76) Inventors: Dong-Wook Kim, San Diego, CA (US); Li-Han Chen, San Diego, CA (US); Sungho Jin, San Diego, CA (US); In Kyung Yoo, Kyongki-do (KR)

Correspondence Address: HARNESS, DICKEY & PIERCE, P.L.C., P.O. BOX 8910, RESTON, VA, 20195, US

(21) Appl. No.: 11/223,135

(22) Filed: Sep. 12, 2005

Related U.S. Application Data
(60) Provisional application No. 60/608,809, filed on Sep. 10, 2004.

(51) Int. Cl. H01L 21/00

(52) U.S. Cl. 438/20

(57) ABSTRACT

Nanotube assemblies and methods for manufacturing the same, including one or more protective layers. A nanotube assembly may include a substrate, a nanotube array, formed on the substrate, and a protective layer, formed on a first area of the substrate where the nanotube array is not, the protective layer reducing the formation of nanocones, and promoting the formation of nanotubes, which make up the nanotube array.

### PRIORITY STATEMENT

This application claims the benefit of U.S. Provisional Patent Application No. 60/608,809, filed on Sep. 10, 2004, in the U.S. Patent and Trademark Office, the disclosure of which is incorporated herein in its entirety by reference.

### FIELD OF THE INVENTION

Example embodiments of the present invention relate to nanotube assemblies and methods for manufacturing the same, and in particular, to nanotube assemblies and methods for manufacturing the same including one or more protective layers.

### DESCRIPTION OF THE RELATED ART

Carbon nanotubes exhibit worthwhile electrical and/or mechanical properties due to their unique atomic arrangements, nano-scale structures, and/or interesting physical properties, for example, one-dimensional electrical behavior, quantum conductance, and/or ballistic transport characteristics. Carbon nanotubes have been shown to be useful for a variety of applications, for example, field emission devices, nanoscale electromechanical actuators, field-effect transistors (FETs), nanointerconnects, and/or scanning probe microscope (SPM) probes.

In recent years, growth techniques for carbon nanotubes have been investigated and established. In particular, the growth of vertically aligned multi-walled carbon nanotubes (MWNTs) has been demonstrated using plasma enhanced chemical vapor deposition (PECVD). These results all had MWNTs aligned perpendicular to a substrate surface due to the applied field or electrical self-bias field created by the plasma environment.

PECVD is a relatively new technique for growing carbon nanotubes, but it has been actively investigated due to its ability to produce vertically-aligned nanotubes. The use of plasma may also lower the growth temperature to approximately 700° C., which may enable the synthesis of the nanotubes to be more compatible with conventional semiconductor fabrication processes. For example, catalyst layers including thin films of Ni, Co, Fe, etc. may be patterned to form nano-sized dots on the substrate to obtain a uniformly spaced nanotube array. This kind of patterning may make it possible to tailor the geometry (for example, diameter controlled by catalyst size, height controlled by deposition time) of the nanotubes to meet the demands of various applications.

However, a relatively low process temperature may result in a large concentration of structural defects (for example, ‘herringbone’ structures with non-parallel graphene sheets and the ‘bamboo’ structures) and the plasma-related complications in composition of the tubes. Under certain growth conditions, the nanotubes may no longer maintain the intended tube geometry and may change into a defective shape, for example, a nanocone geometry which may exhibit undesirably thickened diameter, significant chemical contamination with Si, and/or deteriorated electrical conductivity.

### SUMMARY OF THE INVENTION

Example embodiments of the present invention are directed to a carbon nanotube based structural assembly including a silicon base, a protective layer which reduces, prevents, or minimizes the formation of defective, Si-contaminated nanocone-type geometry, and/or promotes more tube-like, aligned carbon nanotube distribution, with the carbon nanotube growth directly on silicon surface.

Example embodiments of the present invention are directed to a carbon nanotube based structural assembly including a surface-blocking protective layer material selected from Zr, Nb, Mo, Hf, Ta, W, Ti, V, Cr, Mn, Cu, Ir, Rh, Ru, Os, Pt, Au, Bi, rare earth elements, alloys containing one or more of these elements, their oxides, their nitrides, and their carbides. Generally, heavier metals provide enhanced stability against sputtering. Intermetallic compounds with stronger interatomic bonding and/or higher melting temperatures, such as AlN, Al₂O₃, GaN, ZnO, TiOₓ, InOₓ, SnO, MgO may also be used.

Example embodiments of the present invention are directed to methods for forming a preventive-layer-induced nanotube structure using plasma enhanced CVD. The protective barrier layer may reduce or minimize the contamination of nanotubes by silicon from the base substrate material through blocking of the plasma etch of silicon and subsequent incorporation into the growing nanotubes.

Example embodiments of the present invention are directed to a structural assembly in which the gate structure in field emitter itself serves as the surface-blocking protective layer that reduces or minimizes the formation of Si-contaminated nanocones.

Example embodiments of the present invention are directed to an article including such nanotube structures with reduced or minimized defect geometry and structural assembly including a surface-blocking protective layer, with such an article including a variety of technical devices, for example, field emission devices, microwave amplifiers, flat panel displays, plasma displays, circuit nano interconnects, nanofabrication patterning tools, and field effect transistors.

Example embodiments of the present invention are directed to a structural assembly including a protective layer and more tube-like, aligned carbon nanotube configuration, which reduces or minimizes the formation of defective nanocone-type geometry.

Example embodiments of the present invention are directed to methods for forming such a structure using plasma enhanced CVD. Such structures with reduced or minimized defect geometry may be useful for various applications, such as field emission devices and lower-electrical-resistance devices, such as circuit interconnects and field effect transistors.

Example embodiments of the present invention are directed to a carbon nanotube based structural assembly including a silicon base, a protective layer which reduces, prevents or minimizes the formation of defective nanocone-type geometry, and more tube-like, aligned carbon nanotube distribution.

Example embodiments of the present invention are directed to methods for forming a preventive-layer-induced nanotube structure using plasma enhanced CVD. The protective barrier layer may reduce or minimize the contamination of nanotubes by silicon from the base substrate material through blocking of the plasma etch of silicon and subsequent incorporation into the growing nanotubes. Such nanotube structures with reduced or minimized defect geometry can be useful for a variety of technical applications including field emission devices, circuit nano interconnects and field effect transistors.

### BRIEF DESCRIPTION OF THE DRAWINGS

The present invention will become more apparent by describing in detail example embodiments thereof with reference to the attached drawings.

FIGS. 1A and 1B illustrate a carbon nanocone geometry typically formed on bare Si substrates and a nanotube geometry grown on a Ti-layer-protected Si substrate, respectively.

FIGS. 2A and 2B illustrate example transmission electron microscope (TEM) micrographs of carbon nanocones and carbon nanotubes, respectively.

FIG. 3 illustrates a carbon nanotube array using one or more protective layers according to an example embodiment of the present invention.

FIGS. 4A-4D illustrate a carbon nanotube array using individual protective layers according to an example embodiment of the present invention.

FIGS. 5A-5D illustrate a fabrication process of a carbon nanotube array using individual protective layers according to an example embodiment of the present invention. In particular, FIG. 5A illustrates deposition of a protective layer on a substrate, FIG. 5B illustrates resist patterning, FIG. 5C illustrates etching of the protective layer and deposition of a catalyst thin film, and FIG. 5D illustrates lift off of the catalyst thin film and growth of carbon nanotubes.

FIG. 6 illustrates a carbon nanotube array using a protective layer according to an example embodiment of the present invention.

FIG. 7 illustrates a gated triode field emitter structure according to an example embodiment of the present invention.

FIG. 8 is a SEM micrograph of a gated carbon nanotube field emitter according to an example embodiment of the present invention.

FIG. 9 illustrates an example microwave amplifier including a structural assembly according to an example embodiment of the present the invention.

FIG. 10 illustrates an example field emission display including a structural assembly according to an example embodiment of the present the invention.

FIG. 11 illustrates an example projection e-beam lithography apparatus with a cold cathode including a structural assembly according to an example embodiment of the present the invention.

FIG. 12 illustrates an example plasma display device including a structural assembly according to an example embodiment of the present the invention for low voltage operation of the display.

FIG. 13 illustrates an example carbon nanotube array structure for a nanointerconnect according to an example embodiment of the present invention.

FIG. 14 illustrates an example vertical nano-sized transistor using a carbon nanotube as a channel according to an example embodiment of the present invention.

FIG. 15 is a SEM micrograph of a successfully grown single carbon nanotube in a nano-sized hole according to an example embodiment of the present invention.

It is to be understood that these drawings are for the purposes of illustrating the concepts of the invention and are not to scale. For example, the dimensions of some of the elements are exaggerated relative to each other.

### DETAILED DESCRIPTION OF EXAMPLE EMBODIMENTS OF THE PRESENT INVENTION

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Carbon nanotubes may be grown in the form of well-aligned fibers on a substrate. Such vertically aligned and straight nanotube geometry may be useful for certain applications, for example, a field emission source, nanointerconnects, and vertical transistors. CVD growth of carbon nanotubes may require formation of nucleating sites, for example, islands of a catalyst metal such as Co, Ni, or Fe. The diameter, growth rate, and/or aerial density of nanotubes may be controlled by the initial thickness of the catalyst layer.

Catalyst particles may be formed by a natural break up of the catalyst layer into discrete islands or during heating to the CVD reaction temperature. Particle size may depend on the initial film thickness, the underlying surface, and/or the annealing or CVD temperature.

A high anneal/growth temperature may encourage the formation of silicides, which may anchor the catalyst. Such alloying may either promote base growth or deteriorate the catalytic efficiency, if excessive alloying occurs.

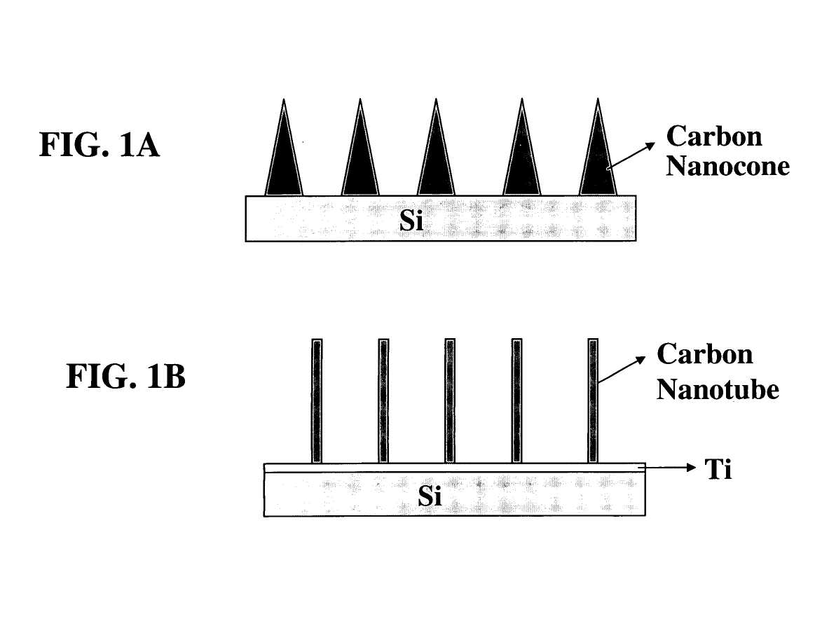

FIGS. 1A and 1B illustrate nanocone and nanotube structures, respectively. A nanocone structure may be formed when nanotube CVD synthesis is carried out on a bare substrate (for example, Si) as shown in FIG. 1A. If the Si substrate is coated with a diffusion barrier material such as Ti, TiN, or SiO₂, a tube-like structure may be formed as illustrated in FIG. 1B. A fabrication process according to an example embodiment of the present invention, for nanocone or nanotube formation is described below.

A 50 Å thick Ni layer, for example, deposited on an Si substrate was annealed at approximately 700° C. in an H₂ atmosphere. Subsequently, a CVD chamber may be evacuated to base pressure (for example, 5×10⁻² Torr) and ammonia (NH₃), for example, may be introduced immediately. A DC bias voltage (for example, approximately 600 V) may be applied between the cathode (the Si substrate) and the anode to initiate discharge. An acetylene (C₂H₂) feed gas, for example, may then be introduced and carbon nanostructures growth was started. The ratio of C₂H₂:NH₃ ratio may be about 1:5 and the pressure may be held at 3 torr during the growth.

Several reasons for nanocone formation and its contamination with Si during the plasma assisted CVD processing for nanotube synthesis may not only be a result of the diffusion of silicon from the substrate to the growing nanotubes, but also the sputter etching (or plasma etching) of silicon surface atoms by the surrounding plasma. The sputter etched Si atoms may go into the surrounding plasma atmosphere first, and then incorporated back into solid, e.g., into the growing nanotubes. Such Si contamination may also be more pronounced when the carbon nanotubes or nanocones are sparsely located, for example, as in the case of electron-beam patterned, periodically spaced apart nanotube configuration. The relative ratio of the available silicon surface area to the number of growing nanocones or nanotubes is much larger in this case.

In example embodiments of the present invention, the surface of nearby silicon substrate area may be blocked and/or covered with a metal layer heavier and/or more stable than Si, and thus more difficult to sputter away. Therefore, a plasma CVD growth of tube-shape nanotubes uncontaminated or minimally contaminated by Si can successfully be accomplished even on a bare Si substrate.

Examples of heavy metals to perform such a blocking and/or covering may include Zr, Nb, Mo, Hf, Ta, W, Ti, V, Cr, Mn, Cu, Ir, Rh, Ru, Os, Pt, Au, Bi, rare earth elements, alloys containing one or more of these elements, their oxides, their nitrides, and their carbides. Generally, heavier metals enhance stability against sputtering. Intermetallic compounds with strong interatomic bonding and/or high melting temperatures, for example, AlN, Al₂O₃, GaN, ZnO, TiOₓ, InOₓ, SnO, MgO may also be used. Metals or alloys that may serve as carbon nanotube nucleating catalyst (for example, Fe, Ni, Co and their alloys) may be less effective as the surface-blocking layer material. Also, SiO₂ layer may be a less effective surface-blocking protective layer because it may be more easily sputter etched.

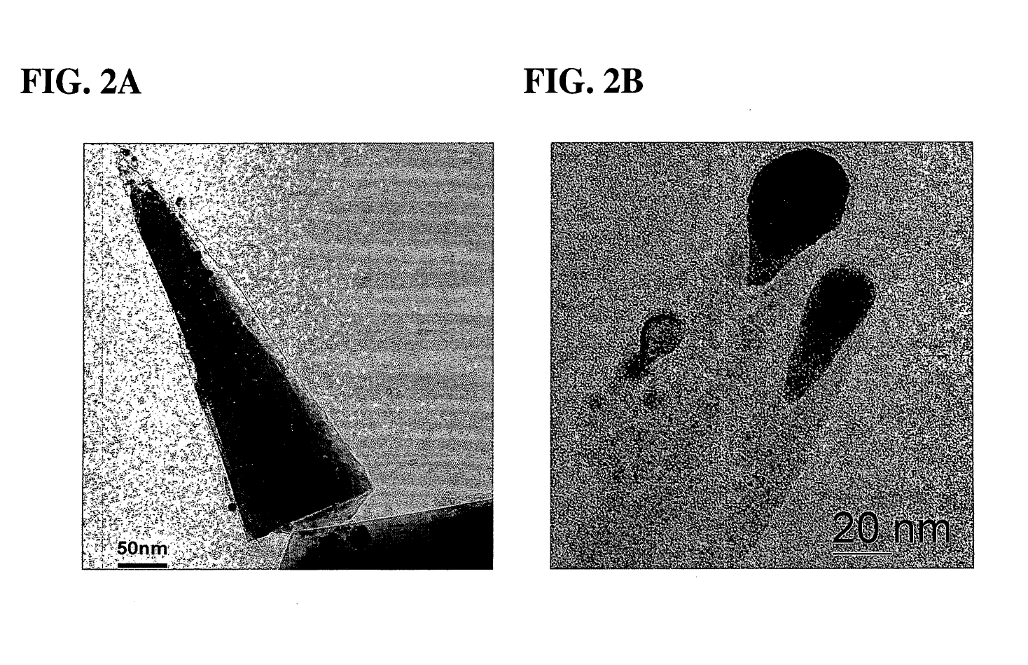

FIGS. 2A and 2B illustrate example TEM micrographs of carbon nanocones and carbon nanotubes, respectively, produced by plasma assisted CVD processing. A carbon nanocone may have an inner cone, which is covered by a thinner outer layer. The cone may be crystalline with internal inclusions. Energy dispersive x-ray analysis (EDX) or energy dispersive spectrometry (EDS) analysis indicates that the cone matrix may be made of mostly silicon and carbon. The tiny inclusions may be mainly composed of Ni. These observations may be explained by the ‘plasma etching’ effect as discussed above.

Silicon is found in the cone everywhere, which indicates that the incorporation of Si into the nanocone frequently occurs during nanotube or nanocone growth. The Ni inclusions in the cone may indicate strong etching (sputtering) and a re-precipitation effect of Ni catalyst particles.

The tube-like structure is shown in FIG. 2B, which has an almost constant diameter and a Ni catalyst particle cap on the growth tip. In contrast, similar EDX analysis on the nanotube sample revealed that they include mostly of carbon with no detectable amount of Si. A small amount of Si may be found only at the very bottom part of carbon nanotubes, presumably caused by some solid state diffusion of silicon atoms from the substrate to the nanotube.

In example embodiments of the present invention, a nanotube structure formed using a surface blocking layer (for example, Si surface blocking), the degree of contamination by Si in the nanotube may be less than 20% by weight, may be less than 5%, and may be less than 2%. The diameter of a nanotube structure, in example embodiments of the present invention, may remain basically constant, possibly with a decrease in diameter near the top end as compared to that near the bottom of less than 30% or less than 10%.

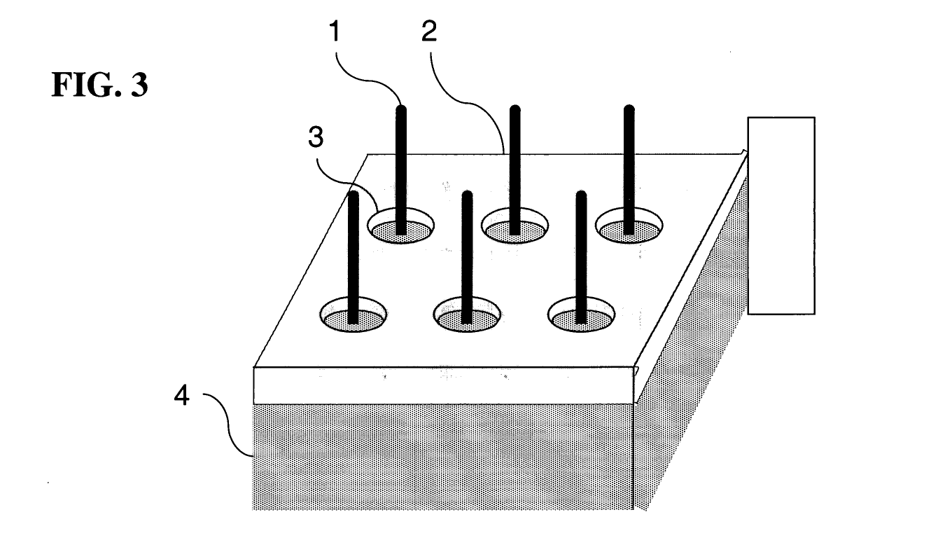

FIG. 3 illustrates an example nanotube-containing structure prepared by a method according to an example embodiment of the present invention, where Si surface blocking is performed during carbon nanotube array growth by PECVD. The example nanotube-containing structure may include bare Si exposed only in selected areas, for example, the circular, apertured areas with the remaining area covered with the surface-blocking material. A carbon nanotube array 1 may be allowed to grow on a bare Si substrate 4 only in the selected areas, e.g., within aperture(s) 3, where the catalyst is placed. The surface-blocking protective layer 2 may reduce or prevent any unwanted sputter etching and re-deposition of Si from the substrate.

The thickness of the surface-blocking protective layer 2 may be in the range of 5-5000 nm or 10-100 nm. The surface-blocking protective layer 2 may be added by known thin film deposition techniques, for example, evaporation, sputtering, electroless coating, electroplating, liquid spinning and/or baking. When the surface-blocking protective layer 2 material includes a metal or compound that does not wet Si well is to be used, a thin adhesion layer of e.g., 2-20 nm thickness may optionally be added at the interface to improve the adhesion. Example of such an adhesion layer may include Cr, Ti, and Zr.

The patterning to expose selected local areas for nanotube growth on bare Si may be carried out by known lithographic techniques, for example, optical lithography, electron beam lithography or deposition of the surface-blocking protective layer 2 through a shadow mask with desired apertured holes. The overall area coverage of the surface-blocking protective layer 2 relative to the bare Si area may be at least 70%, at least 90%, or at least 95%, in order to reduce or minimize the extent of Si sputter etch.

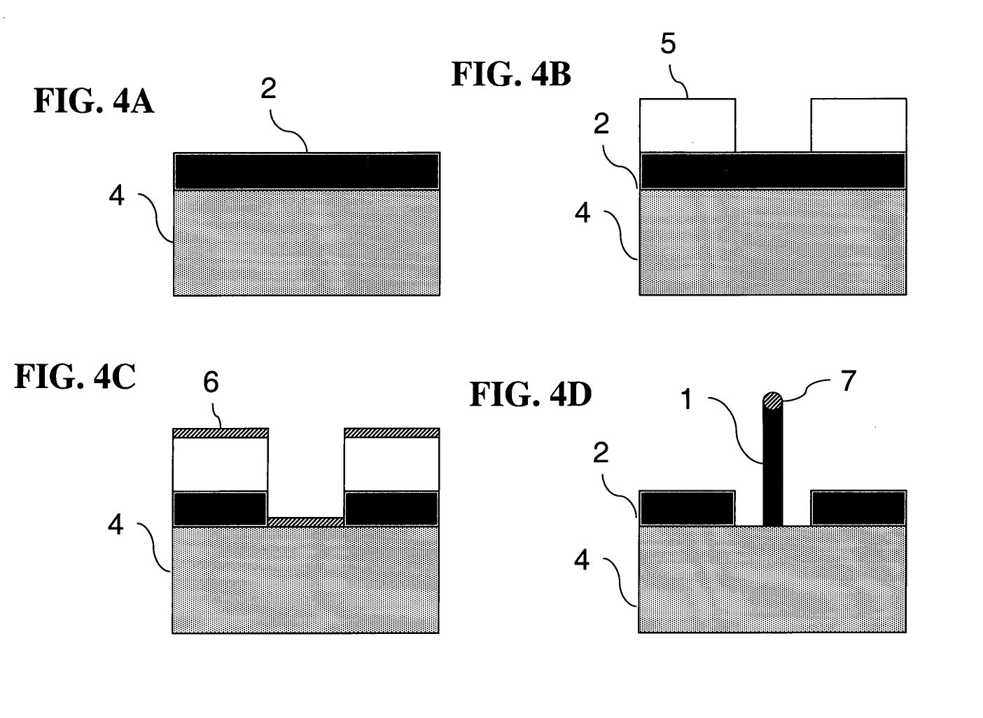

FIGS. 4A-4D illustrate a process of fabricating a surface-blocking layer around the region of carbon nanotube growth, according to an example embodiment of the present invention. For example, a conventional photo lithography process may be used to define an area where a carbon nanotube (or a multitude of carbon nanotubes) is to be grown on bare Si. As shown in FIG. 4A, the substrate 4 may be coated with the surface-blocking layer 2. As shown in FIG. 4B, a resist 5 (for example, polymethylmethacrylate (PMMA)) may be patterned and selected area of the surface-blocking protective layer 2 may be exposed. As shown in FIG. 4C, the exposed apertured layer (which may be circular, oval, square, rectangular or any other shape) may be etched and a catalyst thin film 6, for example, Fe, Co, Ni or their alloys may be deposited.

The resist may be removed and carbon nanotubes 1 may be grown by subsequent plasma CVD processing, for example, in the presence of an applied electric field to ensure the vertical alignment of nanotubes, as shown in FIG. 4D. FIG. 4D illustrates a carbon nanotube grown by a ‘tip’ growth mode. In such a mode, a catalyst nanoparticle 7 may be detached from the substrate during growth and may be found at the tip of the tube after growth. If the adhesion of the catalyst nanoparticle 7 to the substrate 4 (or underlying layer) is strong, they will stay on the substrate and a ‘base’ growth mode occurs.

In either mode, the number of carbon nanotubes per patterned area may depend on the catalyst size. For example, 7 nm thick Ni dots from 100 to 300 nm patterned area may have a single nanotube yield of 100%-88%, respectively. The single nanotubes yield may decrease as the catalyst dot size increases, due to the probability of a catalyst cluster island breaking up into multiple nanoparticles to form multiple nanotubes, instead of a single tube (as illustrated in FIGS. 4A-4D).

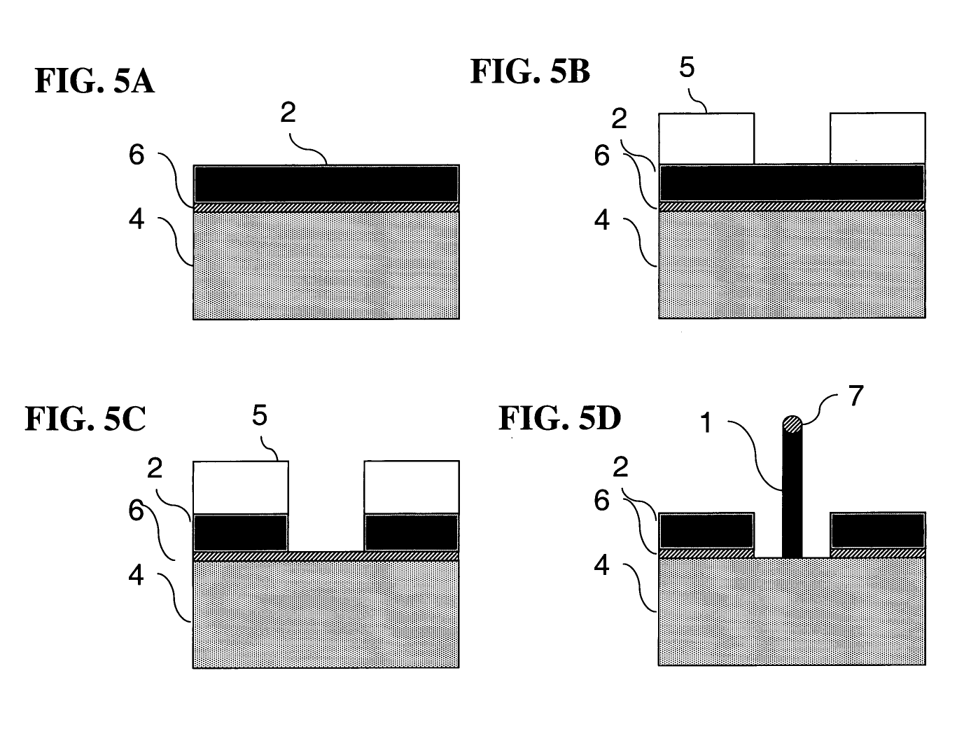

FIGS. 5A-5D illustrate a process of fabricating a surface-blocking protective layer and growing carbon nanotubes according to another example embodiment of the present invention. As shown in FIG. 5A, the substrate 4 may be coated by a catalyst layer 6, and then by a protective layer 2. As shown in FIG. 5B, resist 5 may be patterned to define the area to grow carbon nanotubes. As shown in FIG. 5C, the exposed region not covered by the resist 5 may then be etched away. The etching technique may be chosen so as not to etch or damage the underlying catalyst layer 6. If a tungsten thin film is selected as the surface-blocking protective layer 2, it can be etched by a reactive ion etching in SF₆-based plasma. SF₆-based recipes may etch Si or W and may not significantly affect the catalyst metals. After etching, the carbon nanotubes 1 may be grown, as shown in FIG. 5D. The catalyst layer 6 covered with the surface-blocking protective layer 2 does not allow growth of carbon nanotubes 1.

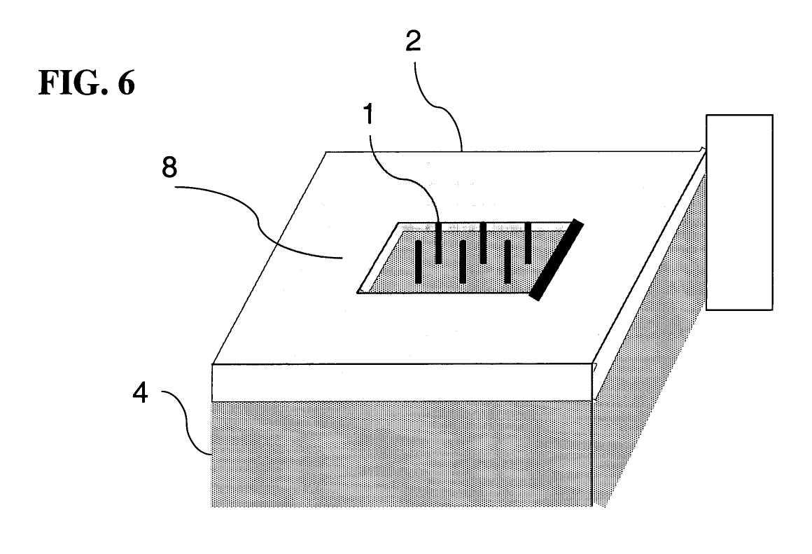

FIG. 6 illustrates another configuration of a carbon nanotube array with a surrounding surface-blocking protective layer according to another example embodiment of the present invention. Here, the nanotube growth region is not individualized so as to allow growth of a multitude of nanotubes. Carbon nanotubes 1 may be grown on a substrate 4 and surrounded by a protective layer 8. The desired area of the opening (apertured region with bare Si surface) relative to the protected area covered with the surface-blocking protective layer 2 may be maintained relatively small, with the ratio of less than 30% or less than 10%, so that available number of sputter etched Si atoms per carbon nanotube is reduced or minimized. This may promote the growth of nanotubes instead of Si-contaminated nanocones.

If the opening (apertured region) is rectangular in shape, a narrow and elongated rectangle area may be used to reduce or minimize the Si contamination of the growing nanotubes from the neighboring Si substrate region. The desired width of the rectangular opening may be at most 100 micrometers, at most 20 micrometers, or at most 5 micrometers.

A structural assembly including carbon nanotubes and apertured surface-blocking protective layers according to example embodiments of the present invention may have one or more desirable characteristics, useful for a number of device applications. They include various choices of underlying layers to grow defect-free carbon nanotubes, which may enable improvement or optimization of the electrical and structural properties independently. Electrical resistance is highly dependent on structural and chemical defects. Incorporation of substrate material, for example, Si into nanotubes can be reduced or minimized using one or more protective layers, which may improve device performance. By reducing or minimizing the occurrence of Si-contaminated, relatively short nanocines, a higher aspect ratio may be achieved in nanotubes, which may lower the turn-on voltage of carbon nanotube field emitters. Some of the device applications utilizing the beneficial effect of the inventive structure are described below.

As described above, one-dimensional structures, for example, carbon nanotubes and nanowires, exhibit excellent field emission properties and may be potential electron sources in various vacuum electronic applications. Carbon nanotube emitters can deliver high brightness electron beams (for example, 10⁹ Am⁻²sr⁻¹V⁻¹s, one order better than today's state of the art Schottky or field emission sources) with a smaller energy spread (for example, 0.2-0.3 eV).

When carbon nanotube emitters are fabricated on conductive substrates, for example, thin metal emitter lines, they may show poor emission uniformity within an array. This may be caused by the sensitivity of the Fowler-Nordheim tunneling process to small variations in nanotube radii and heights, gate diameters, position of the gate holes, and the work function. The addition of resistive layers between the field emitters and the emitter lines may improve the uniformity of field emitter arrays. A lateral resistor mesh may be used to homogenize the emission current and/or prevent short-circuit effect by limiting the electrical current.

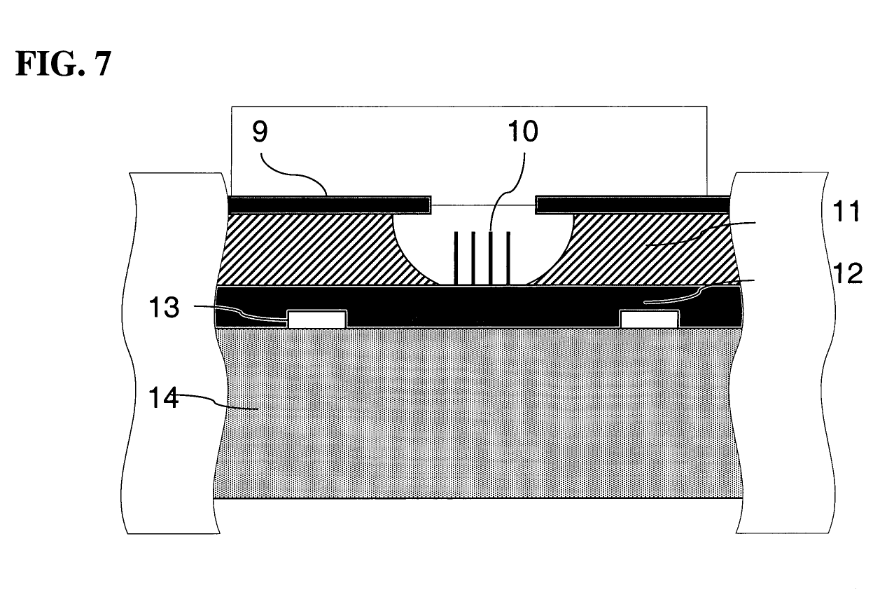

FIG. 7 illustrates a carbon nanotube field emitter fabricated on a resistive sheet according to an example embodiment of the present invention. Each emitter may include a gate electrode 9, a carbon nanotube emitter 10 (with one or more carbon nanotube emitting tips in each emitter cell), an insulator 11, for example, as SiO₂, a resistive layer 12, an emitter conductor line 13, and a substrate (e.g., glass) 14. Optionally, the gate electrodes 9 may be perpendicular to the emitter lines 13, which constitute the matrix structure.

When a positive voltage is applied to the gate electrode 9 with respect to the emitter line 13, the carbon nanotubes may emit electrons. In the matrix structure, each emitter may be located at an intersection zone, where a gate electrode 9 and an emitter line 13 cross. Thus, each emitter may be selectively chosen to emit electrons by applying voltage to the corresponding gate 9 and emitter line 13.

A carbon nanotube emitter 10 may be connected in series to an emitter line 13 and a resistive layer 12. Such a circuit may limit the current during field emission and/or protect the device from excessive current. In general, doped silicon, e.g. having a resistivity of 10⁵ Ωcm and a thickness of 0.1 μm, may be used as the resistive layer, which may be compatible with the process for the production of the field emitters.

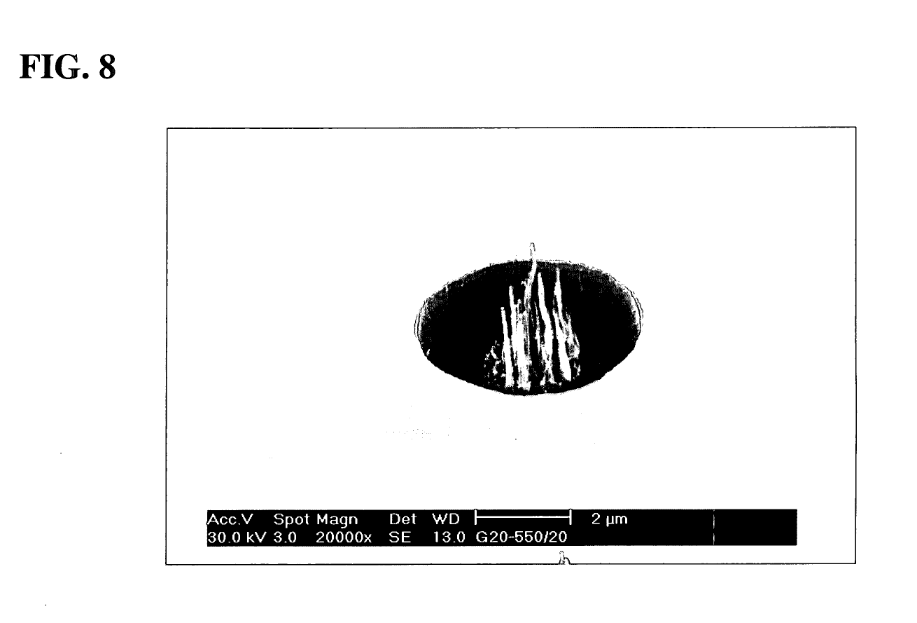

In alternative embodiments of the present invention, the material for the gate layer may be chosen in such a way that the layer also serves as the surface-blocking protective layer, thus serving two purposes at the same time. The problem of plasma etching of Si substrate material may be solved by the gate layer. For example, by using tungsten (W) as the gate layer, plasma etching of Si substrate or the insulator SiO₂ does not occur and thus, the formation of an Si-contaminated nanocone may be prevented. FIG. 8 illustrates a SEM micrograph of tungsten-gated carbon nanotube field emitter prepared according to an example embodiment of the present invention. The gate hole diameter was about 5 μm and the insulator was 1.5 μm thick SiO₂. As tungsten (W) was chosen as a gate metal, Si-contamination of the carbon nanotubes did not occur and a tube-like geometry is maintained as shown in FIG. 8.

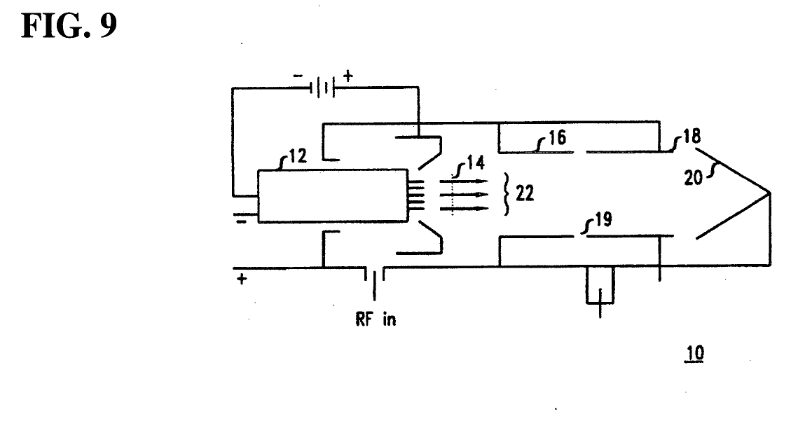

FIG. 9 illustrates a microwave amplifier using nanotubes in accordance with example embodiments of the present invention. Carbon nanotubes are attractive as field emitters because their high aspect ratio (>1,000), one-dimensional structure and/or their relatively small tip radii of curvature approximately 10 nm) tend to effectively concentrate the electric field.

In addition, a beneficial atomic arrangement in a nanotube structure may impart improved mechanical strength and/or chemical stability, both of which make nanotube field emitters robust and stable, especially for high current applications such as microwave amplifier tubes.

Microwave vacuum tube devices, such as power amplifiers, may be essential components of many modern microwave systems, including telecommunications, radar, electronic warfare and navigation systems. While semiconductor microwave amplifiers are available, they generally lack the power capabilities required by most microwave systems.

Microwave vacuum tube amplifiers, in contrast, may provide higher microwave power by orders of magnitude. The higher power levels of vacuum tube devices are the result of the fact that an electron can travel orders of magnitude faster in a vacuum with much less energy loss than the same electron can travel in a solid semiconductor material. Higher electron speed permits the use of a larger structure with the same transit time. A larger structure, in turn, permits a greater power output, which may be required for efficient operations.

Microwave tube devices may operate by introducing a beam of electrons into a region where the beam of electrons may interact with an input signal and derive an output signal from the thus-modulated beam. Microwave tube devices may include gridded tubes, klystrons, traveling wave tubes or crossed-field amplifiers and/or gyrotrons. All may require a source of emitted electrons.

Conventional thermionic emission cathodes, e.g., tungsten cathodes, may be coated with barium or barium oxide, or mixed with thorium oxide, and heated to a temperature of approximately 1000° C. to produce a sufficient thermionic electron emission current on the order of amperes per square centimeter.

The need to heat thermionic cathodes to such high temperatures may cause a number of problems, including limiting the lifetime of the thermionic cathode, introducing warmup delays and/or requiring bulky auxiliary equipment.

Limited lifetime may be a consequence of the higher operating temperature that causes constituents of the cathode, such as barium or barium oxide, to evaporate from the hot surface. When the barium is depleted, the cathode (and hence, the tube) can no longer function. Many thermionic vacuum tubes, for example, have operating lives of less than a year.

Another disadvantage may be the delay in emission from the thermionic cathode due to the time required for temperature ramp-up. Delays up to 4 minutes have been experienced, even after the cathode reaches its desired temperature. This delay length may be unacceptable in fast-warm-up applications, for example, some military sensing and commanding devices.

Yet another disadvantage may be that the high temperature operation requires a peripheral cooling system such as a fan, increasing the overall size of the device or the system in which it is deployed.

Yet another disadvantage may be that the high temperature environment near the grid electrode is such that the thermally induced geometrical/dimensional instability (e.g., due to the thermal expansion mismatch or structural sagging and resultant cathode-grid gap change) does not allow a convenient and direct modulation of signals by the grid voltage alterations.

One or more of these problems and/or other problems may be obviated by a cold cathode and/or a cold-cathode based electron source for microwave tube devices, for example, which do not require high temperature heating.

A cold cathode type microwave amplifier device according to example embodiments of the present invention may use carbon nanotubes to provide electrons for microwave vacuum tubes at low voltage, low operating temperature and/or with fast-turn-on characteristics.

FIG. 9 illustrates a microwave vacuum tube according to an example embodiment of the present invention. The microwave vacuum tube may include a spaced-apart nanowire cold cathode, which may be of “klystrode” type. The klystrode structure may be of gridded tube type (other types of gridded tubes include triodes and tetrodes). The microwave vacuum tube may further include a cathode 12, a grid 14, an anode 16, a tail pipe 18, and/or a collector 20. The microwave vacuum tube may be optionally placed in a uniform magnetic field for beam control. In operation, a RF voltage may be applied between the cathode 12 and grid 14 by one of several possible circuit arrangements. For example, it is possible for the cathode 12 to be capacitively coupled to the grid 14 or inductively coupled with a coupling loop into an RF cavity containing the grid structure. The grid 14 may regulate the potential profile in the region adjacent the cathode 12, and thereby may control the emission from the cathode 12. The resulting density-modulated (bunched) electron beam 22 may be accelerated toward the anode 16 (for example, an apertured anode) at a high potential.

The electron beam 22 may pass a gap 19, called the output gap, in the resonant RF cavity and/or induce an oscillating voltage and current in the cavity. RF power may be coupled from the cavity by an appropriate technique, such as inserting a coupling loop into the RF field within the cavity. Most of the beam passes through the tail pipe 18 into the collector 20. By depressing the potential of the collector 20, some of the DC beam power can be recovered to enhance the efficiency of the device.

Microwave vacuum tubes according to example embodiments of the present invention and associated klystrode structures, may be more efficient because they may combine one or more of the advantages of resonant circuit technologies of high frequency, velocity-modulated microwave tubes (such as klystrons, traveling wave tubes and crossed-field tubes) and those of the grid-modulation technologies of triodes and tetrodes, together with the cold cathodes using high-current emission capabilities of nanowire field emitters according to example embodiments of the present invention. The cold cathodes according to example embodiments of the present invention may allow the grid to be positioned closer to the cathode, for direct modulation of the electron beam signals with substantially reduced transit time.

Because more efficient electron emission may be achieved by the presence of a gate electrode in close proximity to the cathode (for example, about 1-100 μm distance away), it may be desirable to have a finer-scale, micron-sized gate structure with as many gate apertures as possible to increase emission efficiency and/or reduce the heating effect caused by electrons intercepted by the gate grids.

A grid in a cold cathode type vacuum tube device according to example embodiments of the present invention may be made of conductive metals and may have a perforated, mesh-screen or apertured structure to draw the emitted electrons in, yet let the electrons pass through the apertures and move on to the anode. The apertured grid structure can be prepared by photolithographic or other known patterning technique, as is commercially available. The desired average size of the aperture is in the range of 0.5-500 μm, or 1-100 μm, or 1-20 μm.

The grid structure according to example embodiments of the present invention may also be in the form of a fine wire mesh screen, for example, with a wire diameter of 5-50 μm and wire-to-wire spacing (or aperture size) of 10-500 μm. The aperture shape may be circular, square or irregular.

Within each aperture area, a multiplicity of nanotube emitters may be attached on the cathode surface which emits electrons when a field is applied between the cathode and the grid. A more positive voltage may be applied to the anode in order to accelerate and impart a relatively high energy to the emitted electrons. The grid may be a conductive element placed between the electron emitting cathode and the anode. The grid may be separated from the cathode but may be kept sufficiently close in order to induce the emission.

The grid may be separated from the cathode either in a suspended configuration or with an electrically insulating spacer layer, for example, an aluminum oxide layer. The dimensional stability of the grid, more particularly, the gap distance between the cathode and the grid, may be important, for example, in the case of unavoidable temperature rise caused by electron bombardment on the grid and resultant change in dimension or geometrical distortion. It may be desirable that the grid be made with a mechanically strong, higher melting point, and/or lower thermal expansion metal, for example, a refractory or transition metal. The use of mechanically strong and/or creep-resistant ceramic materials, for example, higher conductive oxides, nitrides, carbides, may also be an option. The grid may also be configured to have as much mechanical rigidity as possible.

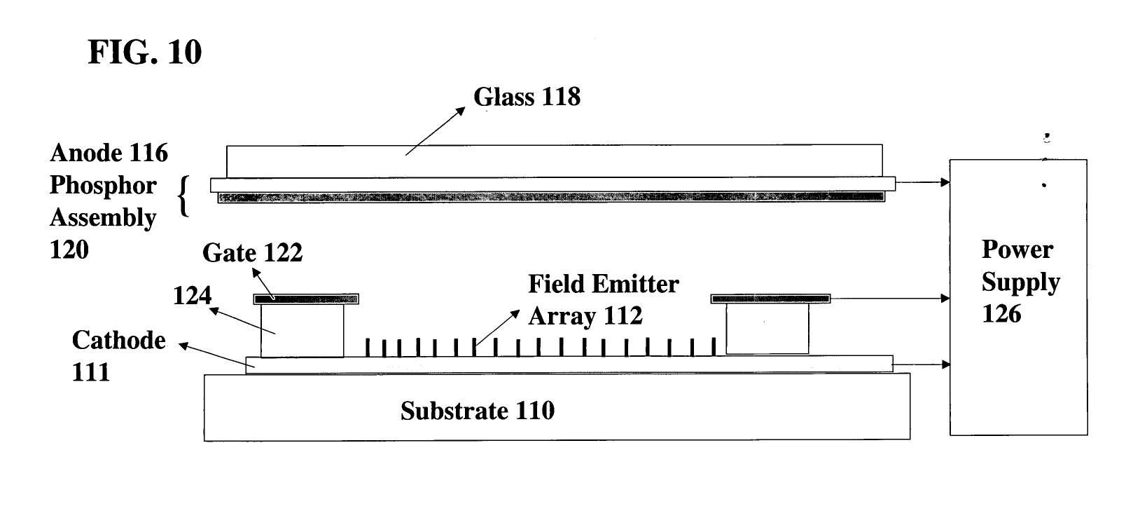

The open-ended nanotube emitters as described in example embodiments of the present invention may also be utilized to make, flat-panel, field emission displays, for example, as illustrated in FIG. 10. Herein, the term “flat panel displays” is arbitrarily defined as meaning “thin displays” with a thickness of e.g., less than approximately 10 cm.

Field emission displays may be constructed with either a diode design (e.g., a cathode-anode configuration) or a triode design (e.g., cathode-grid-anode configuration). The use of grid electrode may be preferred as the field emission may be more efficient. In an example embodiment, the electrode may be a higher density aperture gate structure placed in proximity to the nanotube emitter cathode to excite emission. A high density gate aperture structure may be obtained e.g., by lithographic patterning.

For display applications, emitter material (the cold cathode) in each pixel of the display may include multiple emitters for the purpose, among others, of averaging out the emission characteristics and ensuring uniformity in display quality. Due to the nanoscopic nature of the nanowires, for example, carbon nanotubes, the emitter may provide multiple emitting points, but due to desired field concentrations, the density of nanotubes in example embodiments may be limited to less than 100/(μm)².

Because more efficient electron emission at lower applied voltage may be improved by the presence of an accelerating gate electrode in proximity (for example, about 1 μm distance), it may be useful to have multiple gate apertures over a given emitter area to more efficiently utilize the capability of multiple emitters. It may also be desirable to have a finer-scale, micron-sized structure with as many gate apertures as possible for improved emission efficiency.

A field emission display according to an example embodiment of the present invention is illustrated in FIG. 10 and may include a substrate 110, which may also act as a conductive cathode, a plurality of spaced-apart, and aligned nanotube emitters 112, attached on the conductive substrate 110, and an anode, disposed in a spaced relation from the plurality of emitters 112 within a vacuum seal. A transparent anode conductive layer 116 formed on a transparent insulating substrate 118 (for example, glass) may be provided with a phosphor layer 120 and mounted on support pillars (not shown). Between the cathode 111 and the anode and closely spaced from the plurality of emitters 112 may be a perforated conductive gate layer 122. The gate 122 may be spaced from the cathode 111 by a thin insulating layer 124.

The space between the anode and the plurality of emitters 112 may be sealed and evacuated and voltage may be applied from a power supply 126. The field-emitted electrons from the plurality of emitters 112 may be accelerated by the gate electrode 122, and move toward the anode conductive layer 116 (for example, a transparent conductive layer such as indium-tin-oxide) coated on the anode substrate 118. The phosphor layer 120 may be disposed between the plurality of emitters 112 and the anode. As the accelerated electrons hit the phosphor of the phosphor layer 120, a display image may be generated.

Nano fabrication technologies may be crucial for construction of new nano devices and systems, as well as, for manufacturing of next generation, higher-density semiconductor devices. Conventional e-beam lithography, with single-line writing characteristics, is inherently slow and costly. Projection e-beam lithography technology, which is sometimes called as SCALPEL, may be able to handle approximately 1 cm² type exposure at a time with an exposure time of <1 second.

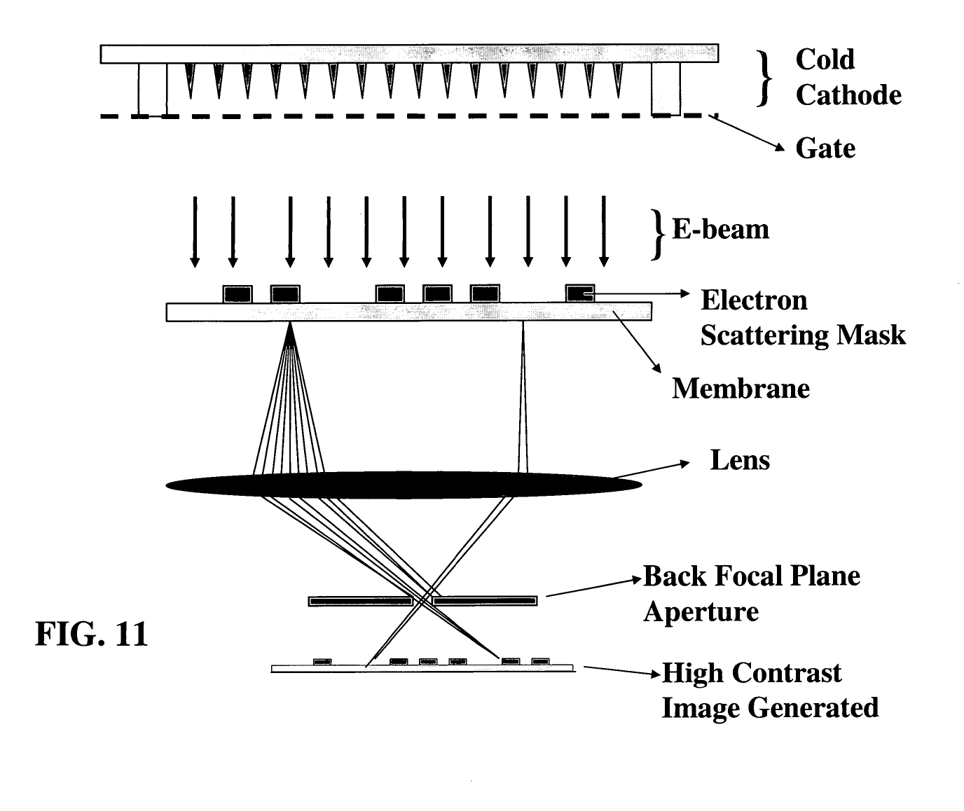

In a projection electron-beam lithography tool according to an example embodiment of the present invention as illustrated in FIG. 11, a mask may include a lower atomic number membrane covered with a layer of a higher atomic number material, and contrast may be generated by utilizing the difference in electron scattering characteristics between the membrane material and the patterned mask material. The membrane may scatter electrons weakly and to small angles, while the patterned mask layer may scatter electrons strongly and to high angles. An aperture in the back focal plane of the projection optics may block the strongly scattered electrons, forming a high contrast image at the wafer plane to be e-beam patterned as illustrated in FIG. 11.

In example operation of the projection electron-beam lithography tool, the mask may be uniformly illuminated by a parallel beam of, e.g., 100 keV electrons generated by a cold cathode according to an example embodiment of the present invention further including open-ended nanotube array field emitters according to an example embodiment of the present invention. A reduction-projection optic, produces, for example, a 4:1 demagnified image of the mask at the wafer plane. Magnetic lenses can be used to focus the electrons. Projection e-beam lithography operations based on a 1:1 projection may also be applied.

Open-ended nanotube array structures according to example embodiments of the present invention may also be useful in improving the performance and/or reliability of flat panel plasma displays. Plasma displays utilize emissions from regions of low pressure gas plasma to provide electrodes within visible display elements. A typical display cell may include a pair of sealed cell containing a noble gas. When a sufficient voltage is applied between the electrodes, the gas may ionize, form a plasma, and/or emit visible and/or ultraviolet light. Visible emissions from the plasma can be seen directly. Ultraviolet emissions can be used to excite visible light from phosphors. An addressable array of such display cells may form a plasma display panel. In an example embodiment, display cells may be fabricated in an array defined by two sets of orthogonal electrodes deposited on two respective glass substrates. The region between the substrates may be filled with a noble gas, for example, neon, and sealed.

Plasma displays have found widespread applications ranging in size from small numeric indicators to large graphics displays. Plasma displays are contenders for future flat panel displays for home entertainment, workstation displays and/or HDTV displays. Using a lower work function material to lower the operating voltage has been described. Open-ended nanotubes according to example embodiments of the present invention may provide improved plasma displays as the more efficient electron emission from the open-ended nanotubes may allows the operation of plasma displays at reduced operating voltages, higher resolution, and/or enhanced robustness.

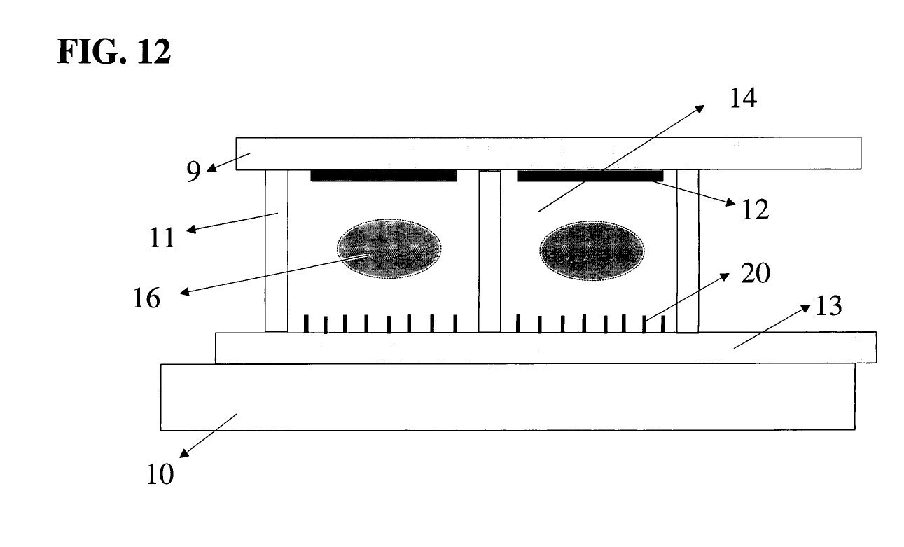

FIG. 12 illustrates a display cell in accordance with an example embodiment of the present invention. The display cell may include a pair of plates 9 and 10 (for example, glass plates), separated by barrier ribs 11. One plate, for example, plate 9 may include an anode 12 (for example, a transparent anode). The other plate for example, plate 10 may include a cathode 13. The plates 9, 10 may be made of soda lime glass. The anode 12 may be a metal mesh or an indium-tin-oxide (ITO) coating. The cathode 13 may be either metal, for example, Ni, W and stainless steel or a conductive oxide. A noble gas 14, for example, neon, argon or xenon (or mixtures thereof) may fill the space between the electrodes. The barrier ribs 11 may be dielectrics and may separate plates 9, 10 by approximately 200 μm.

In operation, a voltage from a power supply 15 may be applied across the electrodes. When the applied voltage is sufficiently high, a plasma 16 forms and emits visible and/or ultraviolet light. The presence of a nanotube structure 20, in accordance with an example embodiment of the present invention, may allow the plasma 16 to be generated at lower voltages because electron emission from the nanowire under an electrical field or upon collision with ions, metastables and photons are much easier than with conventional materials. This facilitated emission may reduce power consumption, simplify the driver circuitry, and/or permit higher resolution.

Trends in electronic circuit design, interconnection and packaging are toward the use of finer features, for example, submicron feature sizes. To produce desired, ultra-high density electronic packaging, a small width of the circuit lines may be useful, as well as a three-dimensional, multi-layer configuration with vertically integrated circuit layers. Multiwalled carbon nanotubes (MWNTs) may be potential candidates as interconnects to meet such demands of future large-scale integrated nanoelectronic devices. The current-carrying capacity and reliability studies of MWNTs under high current densities (>10⁹ A/cm²) show that no observable failure in the nanotube structure and no measurable change in the resistance are detected at temperatures up to 250° C. and for time scales up to 2 weeks.

Multi-wall nanotubes (MWNTs), for example, those made by PECVD may be prepared in an aligned and parallel configuration. Such PECVD-grown MWNTs may be implemented in nanointerconnects. A vertically-interconnected circuit device may have at least two circuit layers and a plurality of substantially equi-length nanowires disposed therebetween. However, these PECVD-grown MWNTs may have a much higher concentration of defects than those prepared by an arc-discharge method. Chemical and/or structural defects may increase the electrical resistance. This may result in higher power consumption and/or shorter device lifetime.

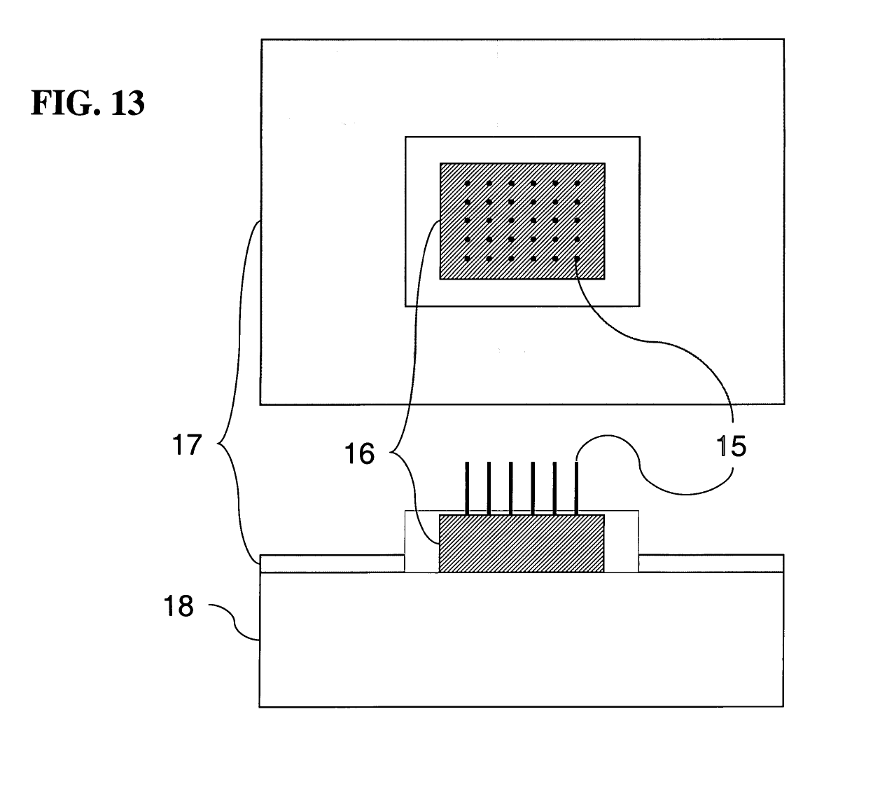

FIG. 13 illustrates a carbon nanotube array for a nanointerconnect in accordance with an example embodiment of the present invention. As shown, vertically aligned MWNTs 15 may be grown on contact pads 16 by PECVD. The substrate 18 may be covered by one or more surface-blocking protective layers 17 to reduce or suppress a supply of unwanted species, for example, Si during nanotube growth. The example embodiment of FIG. 13 is a variation of the surrounded protective layer shown in the example embodiment of FIG. 6.

There is also a continuing trend in semiconductor fabrication to shrink the size of devices thereby increasing the density of the devices in the resulting chip or die. A switching device fabricated using a conventional silicon substrate may be constructed such that an impurity diffusion region, an isolation region and a channel region are horizontally connected on the silicon substrate.

A problem arising from forming an impurity diffusion region and an isolation region on a silicon substrate is that there are limits in processing precision and integration. Switching device using carbon nanotubes may be used to overcome miniaturization problems. Vertically integrated transistor structures using carbon nanotubes have also been proposed.

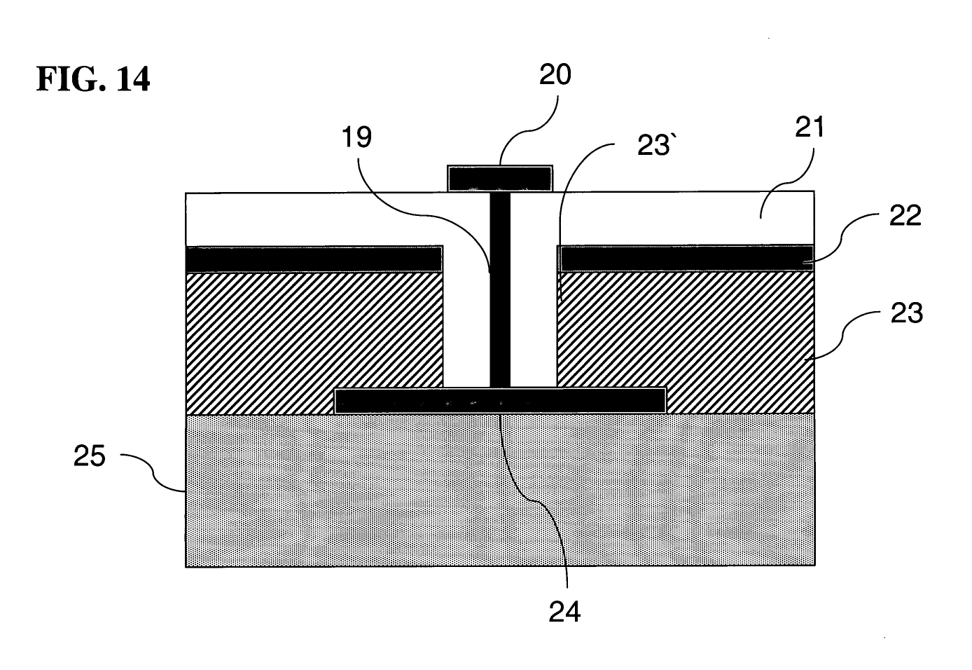

FIG. 14 illustrates a vertical cross-sectional view of a vertical nano-sized transistor using uncontaminated carbon nanotubes according to an example embodiment of the present invention. As shown, one or more carbon nanotubes 19 may be arranged on a substrate 25, having a nano-sized hole 23′. A gate 22 may be formed on an isolation layer 23 in the vicinity of the nanotube 19, and another isolation layer 21 may be deposited to fill the hole 23′. The nanotube 19 may be used as a channel and may be constructed such that the lower and upper parts thereof are connected to a source 24 and drain 20, respectively.

When PECVD is used to grow the carbon nanotube 19, a catalyst thin film may be grown on the source 24 for the vertical and selective growth. To reduce or prevent unwanted species, gate metal 22 may be chosen from the list of desired surface-blocking protective layer materials described above.

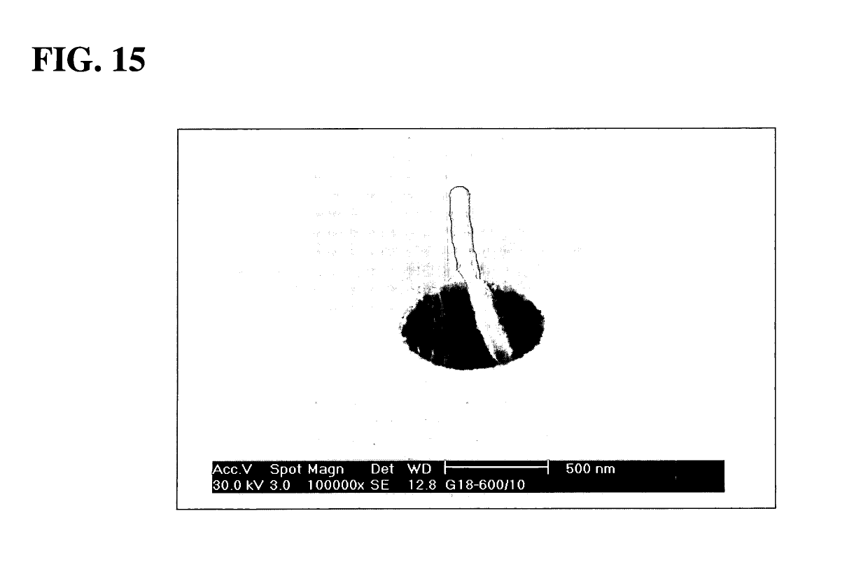

FIG. 15 illustrates an example SEM micrograph of a single carbon nanotube grown at the center of a small gate aperture hole with approximately a 500 nm diameter. The isolation layer is 1.5 μm thick SiO₂ and the gate may be a 200 nm thick W thin film. As in the case of the field emitter array, the gate metal may also be used as a protective layer during the PECVD process. Because of the protection by the tungsten layer, the grown nanotube may not be contaminated by Si, and may have a more uniform diameter in the tube geometry, instead of an Si-contaminated nanocone geometry. As a result, a protective layer works well, even in a vertical transistor structure. Moreover, the reduction or prevention of chemical contamination in the carbon nanotubes, e.g., by Si, may improve proper transistor performance.

It is understood that the above-described embodiments are illustrative of only a few of the many possible specific embodiments which can represent applications of the invention. Numerous and varied other arrangements can be made by those skilled in the art without departing from the spirit and scope of the invention.

What is claimed is:

1. A nanotube assembly comprising:
a substrate;
a nanotube array, formed on the substrate; and
a protective layer, formed on a first area of the substrate where the nanotube array is not, the protective layer reducing the formation of nanocones, and promoting the formation of nanotubes, which make up the nanotube array.

2. The nanotube assembly of claim 1, wherein the protective layer is made of a material heavier than Si.

3. The nanotube assembly of claim 1, wherein the protective layer is made of a material selected from the group consisting of Zr, Nb, Mo, Hf, Ta, W, Ti, V, Cr, Mn, Cu, Ir, Rh, Ru, Os, Pt, Au, Bi, rare earth elements, alloys containing one or more of thereof, oxides thereof, nitrides thereof, and carbides thereof.

4. The nanotube assembly of claim 1, wherein the protective layer material is made of a material selected from the group consisting of intermetallic compounds with stronger interatomic bonding and higher melting temperatures, including AlN, Al₂O₃, GaN, ZnO, TiOₓ, InOₓ, SnO, MgO.

5. The nanotube assembly of claim 1, further comprising:
an adhesion layer, adhering the protective layer to the substrate.

6. The nanotube assembly of claim 1, wherein a second area of the substrate where the nanotube array is, includes one second area and all nanotubes which make up the nanotube array, are on the one second area.

7. The nanotube assembly of claim 1, wherein a second area of the substrate where the nanotube array is, includes a plurality of second areas and each nanotube which makes up the nanotube array, is on a corresponding one of the plurality of second areas.

8. A field emitter, comprising:
the nanotube assembly of claim 1 for emitting an electron beam, wherein the protective layer acts as a gate electrode and the nanotube array acts as an emitter;
a resistive layer;
an insulator between the protective layer and the resistive layer; and
the protective layer and at least one emitter line forming a matrix structure.

9. A microwave amplifier, comprising:
a cathode, including the nanotube assembly of claim 1, for emitting an electron beam;
a grid, located on the cathode to regulate a potential profile of the electron beam in the region adjacent the cathode;
an anode, by which the electron beam is passed; and
a collector, collecting the electron beam.

10. A field emission display, comprising:
the nanotube assembly of claim 1 for emitting an electron beam, wherein the protective layer acts as a gate electrode, the substrate acts as a conductive cathode and the nanotube array acts as a field emitter array; and
an anode, including an anode substrate and a phosphor assembly, electrons impinging on the phosphor assembly to generate a display, a space between the anode and nanotube assembly being under vacuum.

11. A projection electron-beam lithography tool, comprising:
the nanotube assembly of claim 1 for emitting an electron beam, wherein the nanotube assembly acts as a cold cathode and the protective layer acts as a gate electrode;
a scattering mask, including at least two membranes of different atomic number, for scattering the electron beam; and
a focusing assembly for focusing the scattered electron beam to form an image.

12. A display cell, comprising:
a cathode including the nanotube assembly of claim 1 for emitting an electron beam; and
an anode including a mesh, a space between the anode and nanotube assembly being filled with a noble gas.

13. A nanointerconnect, comprising:
the nanotube assembly of claim 1 for emitting an electron beam; and
contact pads on which the nanotube assembly of claim 1 is located.

14. A transistor, comprising:
the nanotube assembly of claim 1;
at least one isolation layer on the substrate, at least one hole in the substrate, the at least one isolation layer, and the protective layer, acting as a gate, a nanotube of the nanotube array located in the at least one hole;
a source on the substrate, at one end of the nanotube of the nanotube array; and
a drain on the at least one isolation layer, at another end of the nanotube of the nanotube array.

15. A method of forming a protective layer on a nanotube assembly comprising:
coating a substrate with the protective layer;
patterning the protective layer to expose areas of the substrate;
depositing a catalyst layer on the exposed areas of the substrate;
removing the pattern and growing the nanotube assembly using the catalyst on the exposed areas of the substrate.

16. The method of claim 15, wherein the nanotube assembly is grown by plasma enhanced chemical vapor deposition.

17. The method of claim 15, wherein the nanotube assembly is grown by one of a tip growth mode and a base growth mode.

18. A method of forming a protective layer on a nanotube assembly comprising:
coating a substrate with a catalyst layer;
coating the catalyst layer with the protective layer;
patterning the catalyst layer and the protective layer to expose areas of the substrate;
removing the pattern and growing the nanotube assembly using the catalyst on the exposed areas of the substrate.

19. The method of claim 18, wherein the nanotube assembly is grown by plasma enhanced chemical vapor deposition.

20. The method of claim 18, wherein the nanotube assembly is grown by one of a tip growth mode and a base growth mode.
